(19) United States
(12) Patent Application Publication
(10) Pub. No.: US 2025/0374646 A1
(43) Pub. Date: Dec. 4, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Jia-Ni YU, New Taipei City (TW); Lung-Kun CHU, New Taipei City (TW); Chun-Fu LU, Hsinchu (TW); Chung-Wei HSU, Hsinchu (TW); Shih-Hao LAI, Hsinchu (TW); Kuo-Cheng CHIANG, Hsinchu (TW); Chih-Hao WANG, Hsinchu (TW)

(21) Appl. No.: 19/295,556

(22) Filed: Aug. 9, 2025

Related U.S. Application Data
(63) Continuation of application No. 18/599,416, filed on Mar. 8, 2024.
(60) Provisional application No. 63/605,704, filed on Dec. 4, 2023.

(51) Int. Cl. H10D 64/68; H01L 21/02; H10D 30/01; H10D 30/43; H10D 30/67; H10D 62/10; H10D 64/01; H10D 64/23

(52) U.S. Cl. CPC H10D 64/681; H01L 21/02337; H10D 30/014; H10D 30/43; H10D 30/6735; H10D 30/6757; H10D 62/121; H10D 64/01; H10D 64/017; H10D 64/258

(57) ABSTRACT

A semiconductor device structure and methods of forming the same are described. The structure includes a first gate dielectric layer disposed over a substrate, the first gate dielectric layer includes an inner surface and an outer surface opposite the inner surface, and the first gate dielectric layer includes a fluorine concentration that decreases from the inner surface towards the outer surface. The structure further includes a second gate dielectric layer disposed on the first gate dielectric layer, the first and second gate dielectric layers have a combined thickness, and a thickness of the first gate dielectric layer ranges from about 30 percent to about 80 percent of the combined thickness. The structure further includes a gate electrode layer disposed over the second gate dielectric layer and a spacer disposed adjacent the first gate dielectric layer.

### CROSS-REFERENCE TO RELATED APPLICATIONS

This application is a continuation application of U.S. patent application Ser. No. 18/599,416, filed Mar. 8, 2024, which claims priority to U.S. Provisional Application No. 63/605,704, filed on Dec. 4, 2023, both are incorporated by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 are perspective views of various stages of manufacturing a semiconductor device structure, in accordance with some embodiments.

FIGS. 6-9 are cross-sectional side views of various stages of manufacturing the semiconductor device structure taken along line A-A of FIG. 5, in accordance with some embodiments.

FIG. 10 is a perspective view of the semiconductor device structure of FIG. 9, in accordance with some embodiments.

FIGS. 11-17 are cross-sectional side views of various stages of manufacturing the semiconductor device structure taken along line A-A of FIG. 10, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

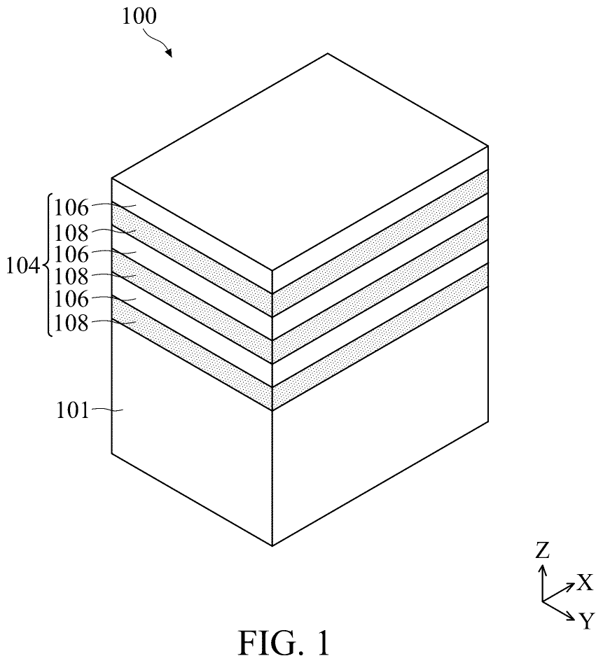

FIGS. 1-17 show exemplary processes for manufacturing a semiconductor device structure 100 according to embodiments of the present disclosure. It is understood that additional operations can be provided before, during, and after processes shown by FIGS. 1-17, and some of the operations described below can be replaced or eliminated, for additional embodiments of the method. The order of the operations/processes is not limiting and may be interchangeable.

FIGS. 1-5 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each first semiconductor layer 106 may have a width in a range between about 4 nm and about 10 nm and a length in a range between about 10 nm and about 50 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm, such as between about 8 nm and about 15 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

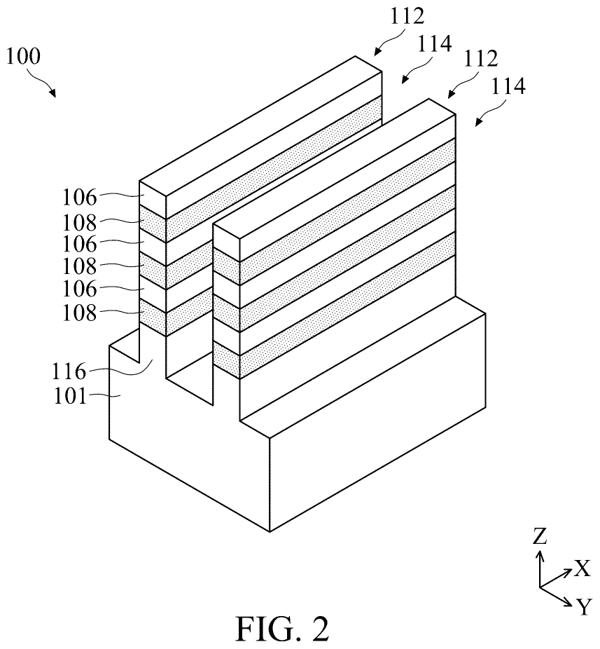

As shown in FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

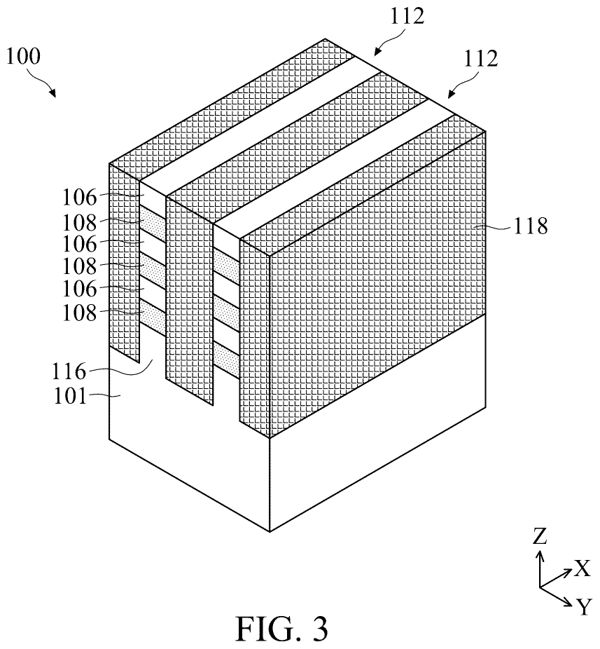

As shown in FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

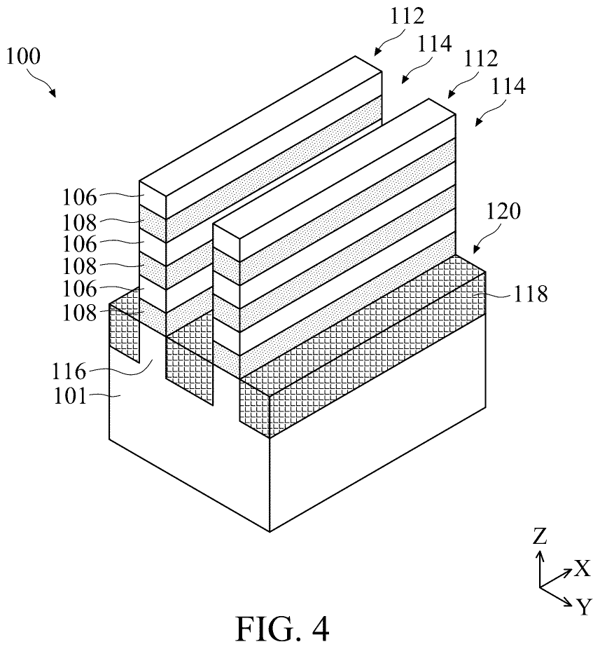

As shown in FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 101.

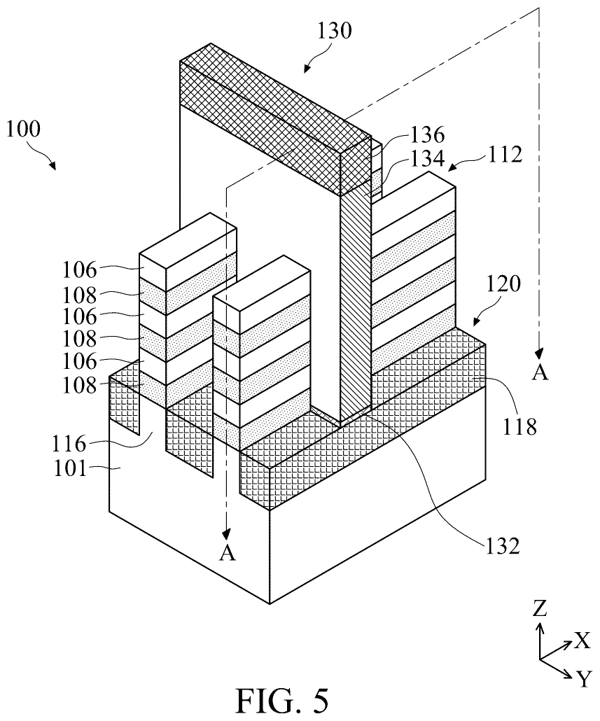

As shown in FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The portions of the fin structures 112 that are covered by the sacrificial gate electrode layer 134 of the sacrificial gate structure 130 serve as channel regions for the semiconductor device structure 100.

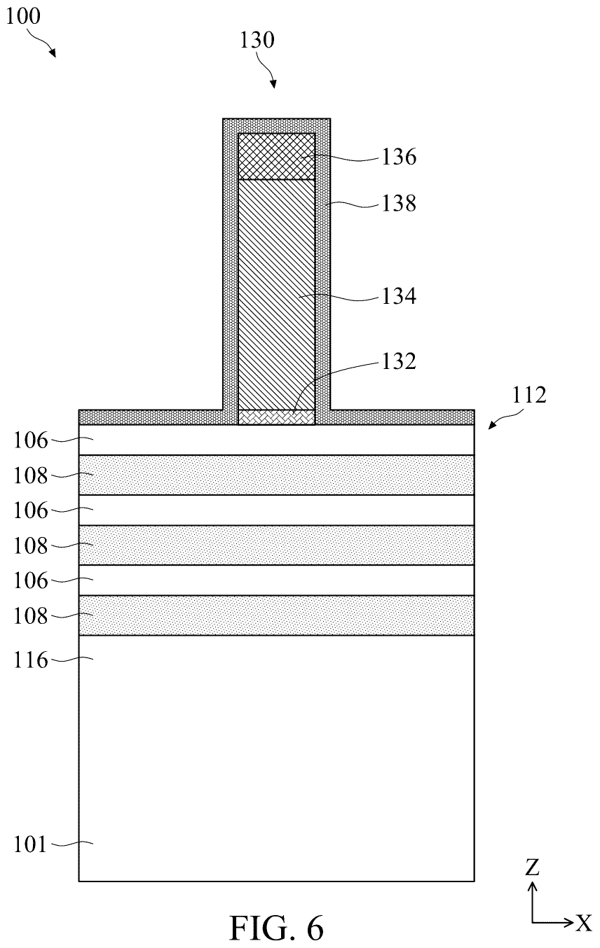

FIGS. 6-9 are cross-sectional side views of various stages of manufacturing the semiconductor device structure 100 taken along line A-A of FIG. 5, in accordance with some embodiments. As shown in FIG. 6, a first spacer 138 is deposited on the exposed surfaces of the semiconductor device structure 100. For example, the first spacer 138 is deposited on the fin structures 112, the isolation regions 120, and the sacrificial gate structure 130. The first spacer 138 may be made of a dielectric material such as silicon oxide, silicon nitride, silicon carbide, silicon oxynitride, SiCN, silicon oxycarbide, SiCON, and/or combinations thereof. In one embodiment, the first spacer 138 is SiCN or SiOC. The first spacer 138 may be formed by any suitable process. In some embodiments, the first spacer 138 is a conformal layer formed by a conformal process, such as an atomic layer deposition (ALD) process.

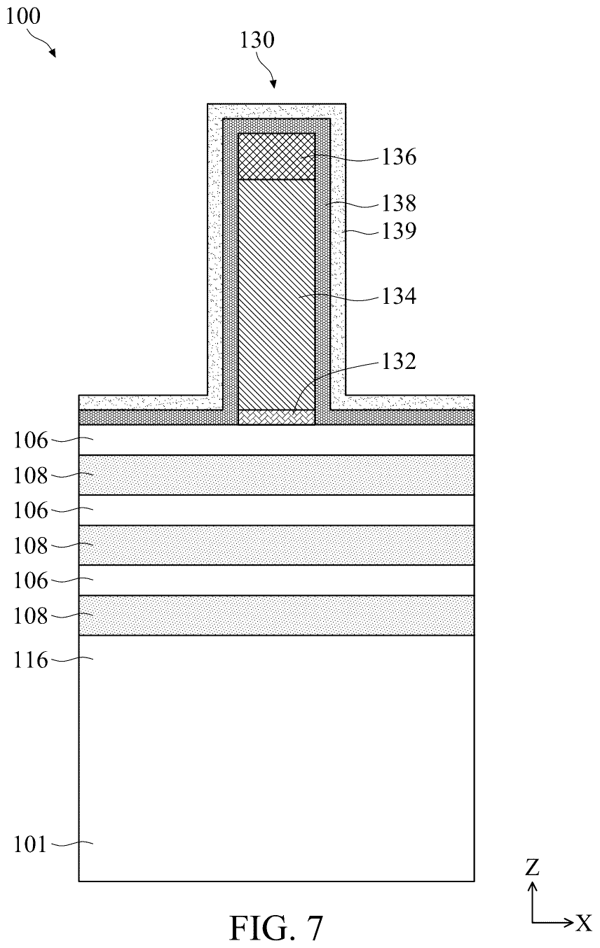

As shown in FIG. 7, a second spacer 139 is deposited on the first spacer 138. The second spacer 139 may include any suitable dielectric material, such as SiOₓ, SiON, SiN, SiCON, or SiCO. The first and second spacers 138, 139 may include the same material. In some embodiments, the first and second spacers 138, 139 may include a material that is chemically different from each other. For example, the first spacer 138 may be SiCN or SiOC and the second spacer 139 may be SiCON.

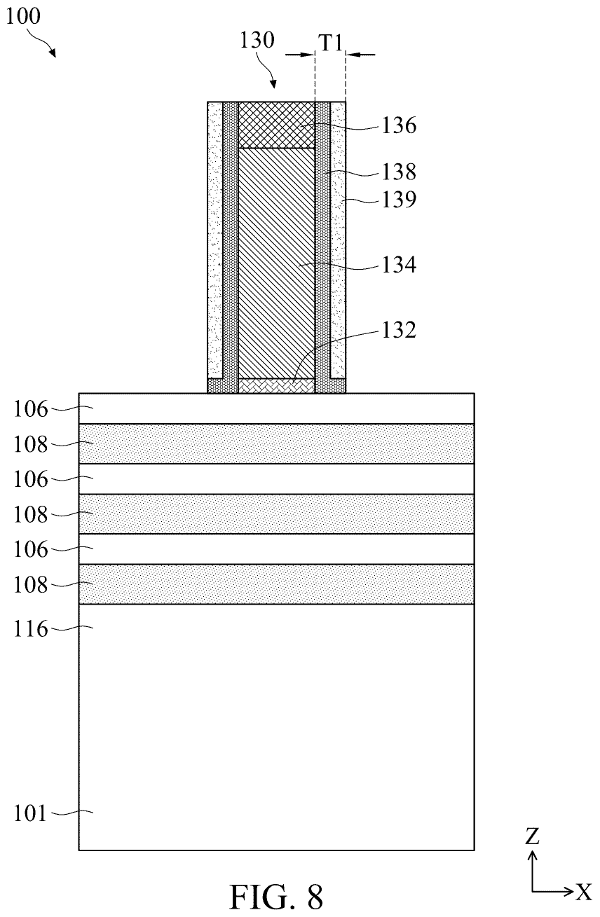

As shown in FIG. 8, horizontal portions of the first and second spacers 138, 139 are removed. In some embodiments, the horizontal portions of the first and second spacers 138, 139 are removed by an anisotropic etch process. The anisotropic etch process may be a selective etch process that does not substantially affect the mask layer 136, the stack of semiconductor layers 104, and the isolation regions 120. The first and second spacers 138, 139 may have a combined thickness T1 in a range of about 4 nm to about 10 nm. The thickness range is applicable to a single spacer (i.e., the first and second spacers 138, 139 are formed of the same material).

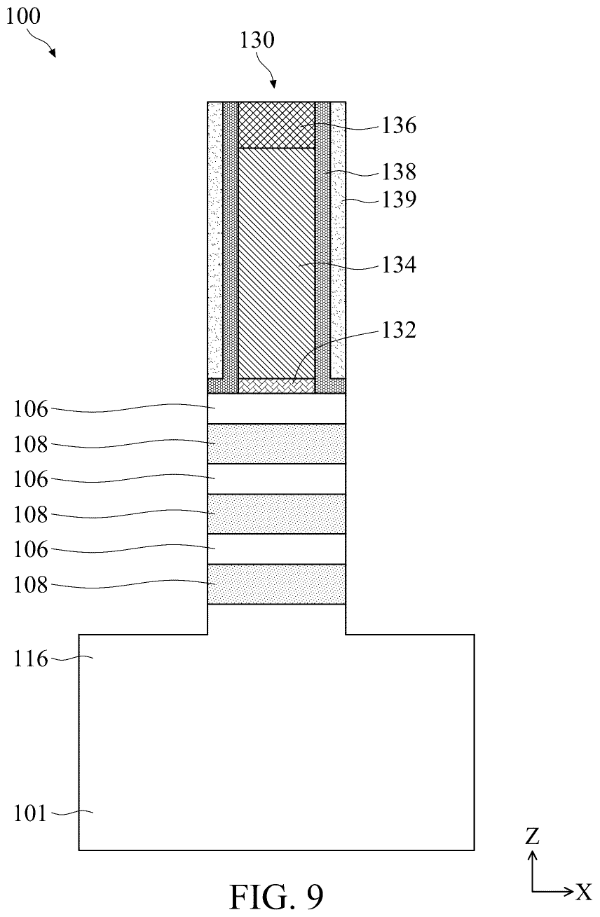

As shown in FIG. 9, the portions of the fin structures 112 not covered by the sacrificial gate structure 130 and the first and second spacers 138, 139 are recessed to a level above, at, or below the top surfaces of the isolation regions 120. The recess of the portions of the fin structures 112 can be done by an etch process. The etch process may be a dry etch, such as a RIE, NBE, or the like, or a wet etch, such as using tetramethyalammonium hydroxide (TMAH), ammonium hydroxide (NH₄OH), or any suitable etchant.

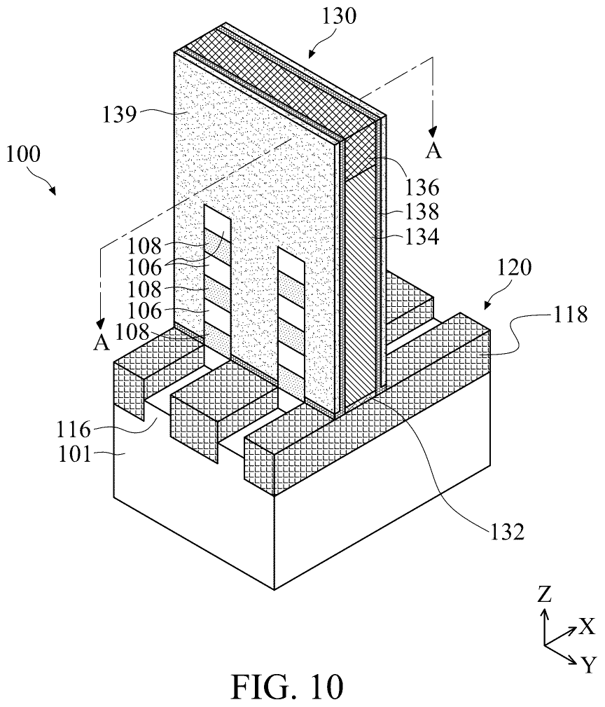

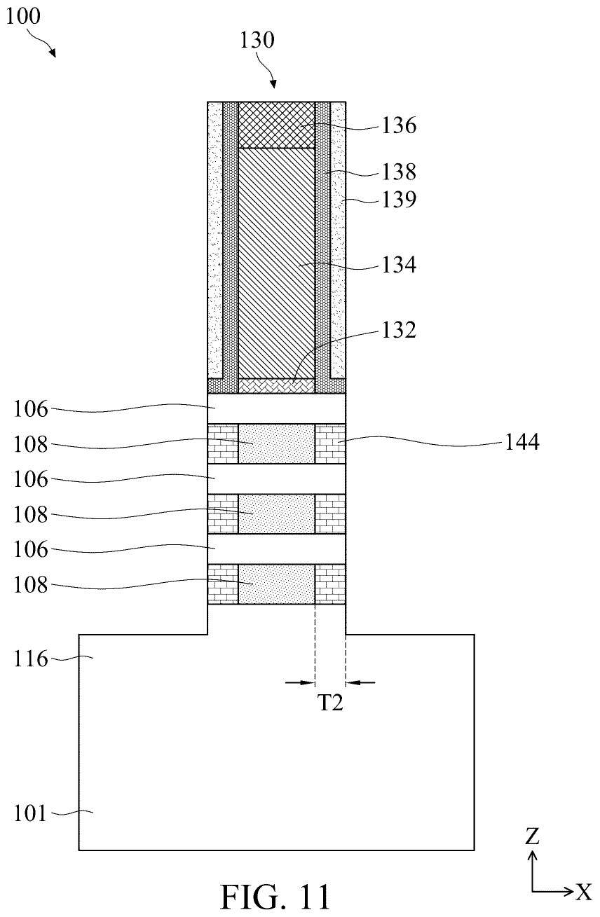

FIG. 10 is a perspective view of the semiconductor device structure 100 of FIG. 9, in accordance with some embodiments. FIGS. 11-17 are cross-sectional side views of various stages of manufacturing the semiconductor device structure taken along line A-A of FIG. 10, in accordance with some embodiments. As shown in FIG. 11, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. In one embodiment, the dielectric spacer 144 includes SiOCN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction. The dielectric spacer 144 may have a thickness T2 in a range of about 4 nm to about 10 nm. In some embodiments, the thickness T2 of the dielectric spacer 144 and the combined thickness T1 of the first and second spacers 138, 139 may be different from each other.

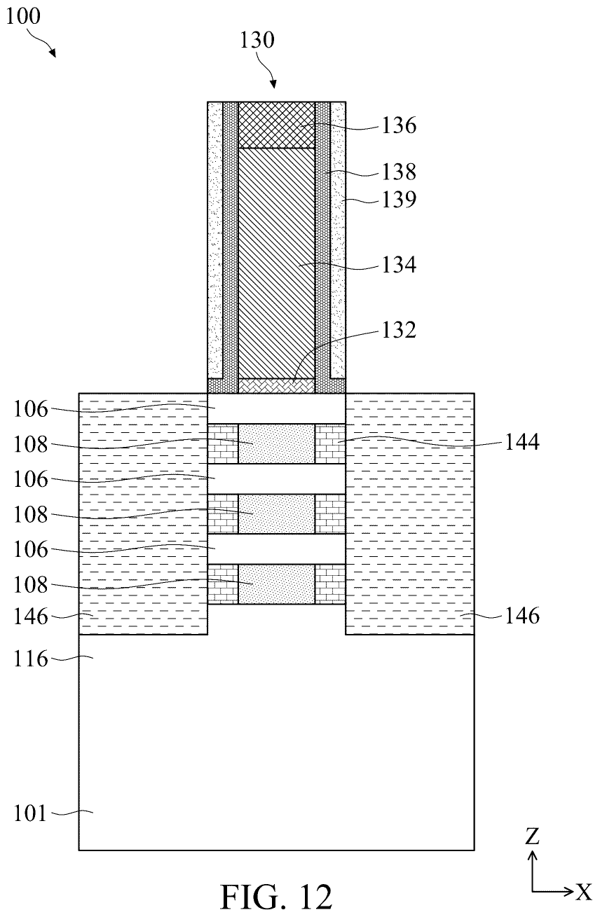

As shown in FIG. 12, source/drain (S/D) regions 146 are formed from the well portion 116. The S/D regions 146 may grow both vertically and horizontally to form facets, which may correspond to crystalline planes of the material used for the well portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

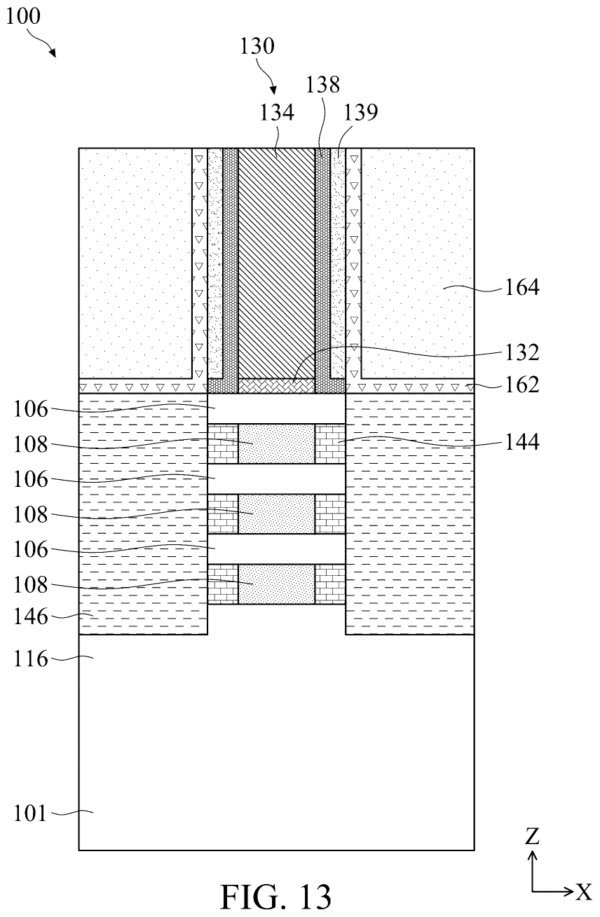

As shown in FIG. 13, a contact etch stop layer (CESL) 162 is conformally formed on the exposed surfaces of the semiconductor device structure 100. The CESL 162 covers the second spacer 139, the isolation regions 120, and the S/D regions 146. The CESL 162 may include an oxygen-containing material or a nitrogen-containing material, such as silicon nitride, silicon carbon nitride, silicon oxynitride, silicon oxide, silicon carbon oxide, or the like, or a combination thereof, and may be formed by CVD, PECVD, ALD, or any suitable deposition technique. In some embodiments, the CESL 162 is a single layer, as shown in FIG. 13. In some embodiments, the CESL 162 includes two or more layers. Next, an interlayer dielectric (ILD) layer 164 is formed on the CESL 162. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIG. 13.

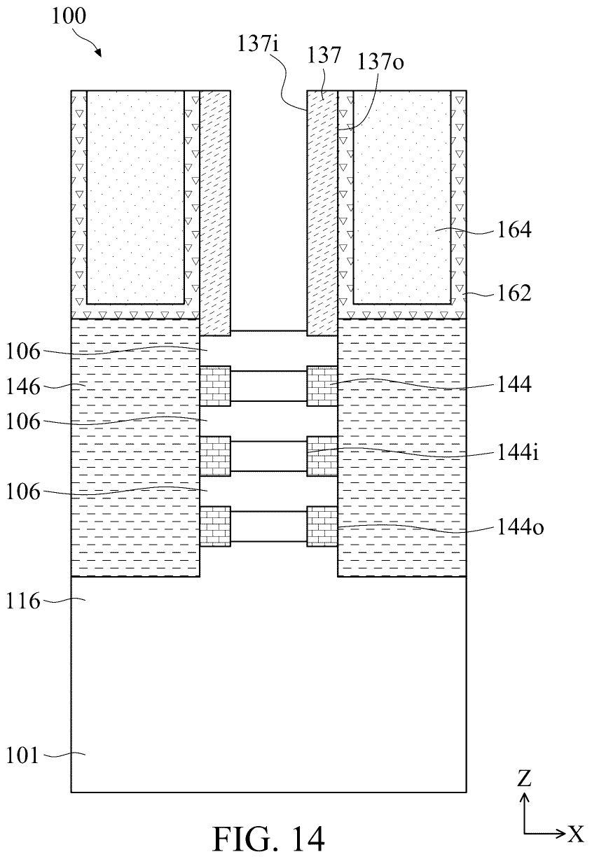

As shown in FIG. 14, the sacrificial gate structure 130 and the second semiconductor layers 108 are removed. The first and second spacers 138, 139 are shown as a single spacer 137, as shown in FIG. 14. The removal of the sacrificial gate structure 130 and the second semiconductor layers 108 forms an opening between the spacers 137 and an opening between the first semiconductor layers 106. The ILD layer 164 protects the S/D regions 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the spacers 137, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the spacers 137, and the dielectric spacers 144. In one embodiment, the second semiconductor layers 108 can be removed using a wet etchant such as, but not limited to, hydrofluoric (HF), nitric acid (HNO₃), hydrochloric acid (HCl), or phosphoric acid (H₃PO₄).

In some embodiments, after the formation of the nanostructure channels (i.e., the exposed portions of the first semiconductor layers 106), a fluorination process is performed to incorporate fluorine into the spacers 137 and the dielectric spacers 144. The fluorination process may be any suitable fluorination process. In some embodiments, the fluorination process is a fluorine soak process. The fluorine soak process may include exposing the spacer 137 and the dielectric spacers 144 to a fluorine-containing precursor at a processing temperature ranging from about 30 degrees Celsius to about 800 degrees Celsius. In some embodiments, the fluorine soak process is a thermal process and is performed without plasma. In some embodiments, the fluorine-containing precursor includes HF, NF₃, CF₄, F₂, C₂F₆, a combination of HF and F₂, or other suitable fluorine-containing precursor. A carrier gas, such as Ar or N₂, may be flowed along with the fluorine-containing precursor. The spacer 137 and the dielectric spacers 144 may be exposed to the fluorine-containing precursor for a duration ranging from about 30 seconds to about 2000 seconds. The fluorinated spacers 137 and dielectric spacers 144 have reduced k-value, such as a reduction by about five percent to about 15 percent, compared to the spacers 137 and the dielectric spacers 144 without fluorine.

In some embodiments, the spacer 137 has an inner surface 137i and an outer surface 137o. After the fluorination process, the fluorine concentration is the highest at the inner surface 137i and gradually decreases towards the outer surface 137o. In some embodiments, first and second spacers 138, 139 are present, and the fluorine concentration decreases from an inner surface of the first spacer 138 towards an outer surface of the second spacer 139. In some embodiments, the second spacer 139 is free of fluorine. In some embodiments, the dielectric spacers 144 has an inner surface 144i and an outer surface 144o. After the fluorination process, the fluorine concentration is the highest at the inner surface 144i and gradually decreases towards the outer surface 144o. In some embodiments, the peak concentration of fluorine in the spacer 137 is located at about 0 nm to about 3 nm away from the inner surface 137i, and the peak concentration of fluorine in the dielectric spacer 144 is located at about 0 nm to about 3 nm away from the inner surface 144i.

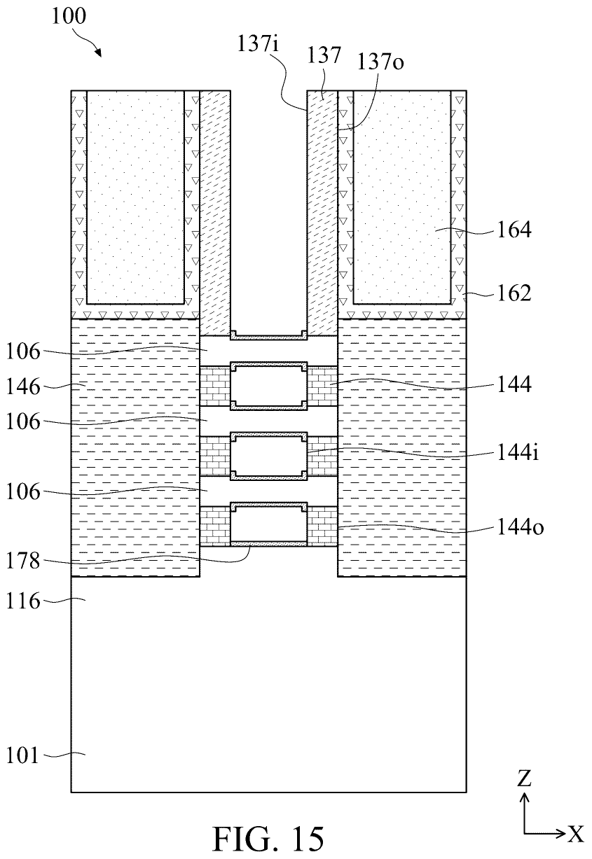

As shown in FIG. 15, an interfacial layer (IL) 178 is formed to surround exposed surfaces of the first semiconductor layers 106. The IL 178 may include or be made of an oxygen-containing material, such as silicon oxide, silicon oxynitride, or oxynitride. In one embodiment, the IL 178 is silicon oxide. The IL 178 may be formed by CVD, ALD, an oxidation process, or any suitable process. The IL 178 may have a thickness of about 0.5 nm to about 2 nm.

In some embodiments, the fluorination process may be performed before the formation of the IL 178 and/or after the formation of the IL 178. In some embodiments, the fluorination process is performed after the formation of the IL 178. The fluorine may diffuse to the interface between the IL 178 and the first semiconductor layer 106 to passivate silicon dangling bonds located thereof. As a result, performance and reliability are improved. The fluorination process performed after the formation of the IL 178 may also fluorinate the spacer 137. In some embodiments, the concentrations of fluorine in the IL 178 and in the spacer 137 are different due to the different materials of the IL 178 and the spacer 137.

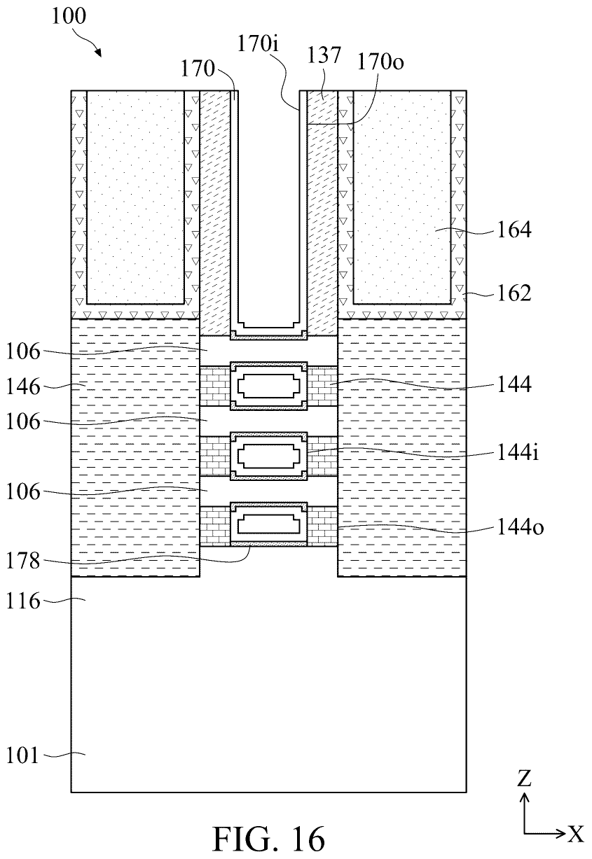

As shown in FIG. 16, a first gate dielectric layer 170 is formed on the IL 178. In some embodiments, the first gate dielectric layer 170 includes a dielectric material, such as silicon oxide, silicon nitride, high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The first gate dielectric layer 170 may be formed by CVD, ALD or any suitable deposition technique. In some embodiments, the fluorination process is performed after the formation of the IL 178, and the first gate dielectric layer 170 can function as a cap layer to prevent fluorine from escaping.

In some embodiments, the fluorination process is performed after the formation of the first gate dielectric layer 170 to incorporate fluorine into the first gate dielectric layer 170. The fluorine in the first gate dielectric layer 170 can passivate oxygen vacancies and traps in the first gate dielectric layer 170. As a result, performance and reliability are improved. In some embodiments, the thickness of the first gate dielectric layer 170 ranges from about 0.5 nm to about 1.5 nm. In some embodiments, the fluorination process is performed after the formation of the IL 178 and before the formation of the first gate dielectric layer 170. The concentration of fluorine may be higher in the IL 178 than in the first gate dielectric layer 170. In some embodiments, the fluorination process is not performed after the formation of the IL 178 and is performed after the formation of the first gate dielectric layer 170. The concentration of the fluorine may be higher in the first gate dielectric layer 170 than in the IL 178. In some embodiments, the first gate dielectric layer 170 has an inner surface 170i and an outer surface 170o. The outer surface 170o may be in direct contact with the spacer 137 and the IL 178. After the fluorination process, the fluorine concentration is the highest at the inner surface 170i and gradually decreases towards the outer surface 170o.

In some embodiments, the fluorination process is performed after the formation of the IL 178 and prior to the formation of the first gate dielectric layer 170. After the formation of the first gate dielectric layer 170, the fluorine may diffuse into the first gate dielectric layer 170. As a result, in some embodiments, the fluorine concentration is the highest at the outer surface 170o and gradually decreases towards the inner surface 170i. In some embodiments, the fluorination process is performed before and after the formation of the first gate dielectric layer 170. As a result, in some embodiments, the fluorine concentration is the highest at the outer surface 170o and the inner surface 170i and gradually decreases towards the center of the first gate dielectric layer 170.

In some embodiments, after the formation of the first gate dielectric layer 170, a dipole process is performed. The dipole process introduces a dipole-engineering dopant (referred to as dipole dopant hereinafter) such as lanthanum, aluminum, yttrium, titanium, magnesium, niobium, gallium, indium or the like into the first gate dielectric layer 170. When diffused into high-k dielectric layers of the first gate dielectric layer 170, the dipole dopants may increase the number of dipoles, and result in the change in threshold voltages (Vts) of the transistors. The effect of different dipole dopants on p-type transistors and n-type transistors may be different from each other. For example, La-based dipole dopant will result in the reduction of the Vt of the n-type transistors, and will increase the Vt of p-type transistors. Conversely, Al-based dipole dopant will result in the increase of the Vt of the n-type transistors, and the reduction in the Vt of p-type transistors.

In some embodiments, a dipole layer (not shown) may be formed on the first gate dielectric layer 170. For n-type device, the dipole layer may include lanthanoid oxide (La₂O₃), yttrium oxide (Y₂O₃), titanium oxide (TiO₂), other n-type dipole material, or combinations thereof. For p-type device, the dipole layer may include aluminum oxide (Al₂O₃), TiO₂, other p-type dipole material, or combinations thereof. The dipole layer for n-type device and p-type device may be different and may be formed at different times using masks. Next, an annealing process is performed. The annealing process may be soak annealing, spike rapid thermal annealing, or the like. The annealing process results in the dipole dopant to be driven into the first gate dielectric layer 170. After the annealing process, the dipole layer is removed by any suitable process.

In some embodiments, the fluorination process is performed before the dipole process. In some embodiments, the fluorination process is performed after the dipole process. With the fluorination process performed before the dipole process, the dipole process may drive the fluorine in the first gate dielectric layer 170 into the spacers 137 and may keep the fluorine in the first gate dielectric layer 170 and the spacers 137.

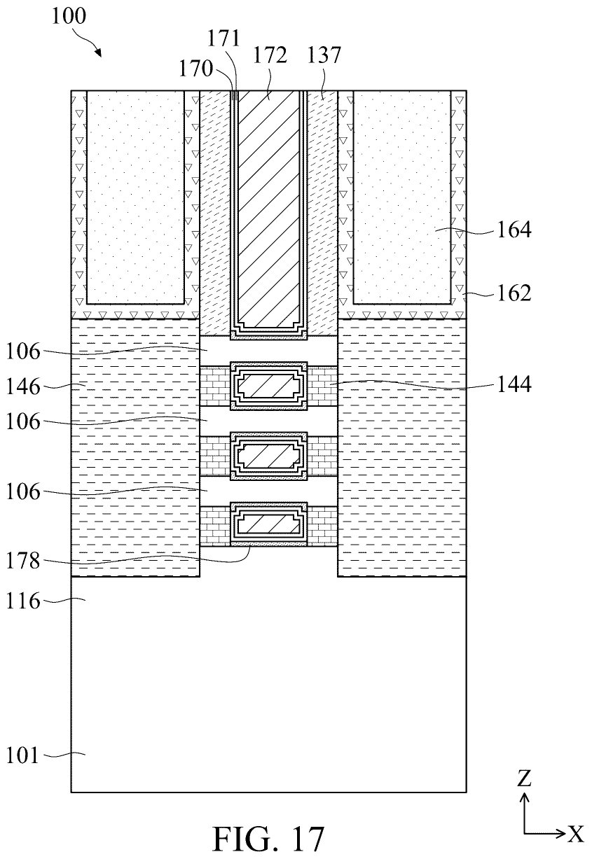

After the formation of the first gate dielectric layer 170, the fluorination process, and the dipole process, a second gate dielectric layer 171 is deposited on the first gate dielectric layer 170, and a gate electrode layer 172 is deposited on the second gate dielectric layer 171, as shown in FIG. 17. In some embodiments, the second gate dielectric layer 171 includes the same material as the first gate dielectric layer 170. The second gate dielectric layer 171 may function as a cap layer to prevent the fluorine in the first gate dielectric layer 170 to escape if the fluorination process is performed after the dipole process. In some embodiments, the first and second gate dielectric layers 170, 171 has a combined thickness, and the thickness of the first gate dielectric layer 170 is about 30 percent to about 80 percent of the combined thickness. If the thickness of the first gate dielectric layer 170 is less than about 30 percent of the combined thickness, the oxygen vacancies in the first and second gate dielectric layers 170, 171 may not be sufficiently passivated. On the other hand, if the thickness of the first gate dielectric layer 170 is greater than about 80 percent of the combined thickness, the fluorine may not be able to diffuse into the spacers 137 and dielectric spacers 144 to reduce the k-value thereof. In some embodiments, the fluorine may diffuse from the first gate dielectric layer 170 to the second gate dielectric layer 171. As a result, the second gate dielectric layer 171 may have a fluorine concentration that decreases from the surface of the second gate dielectric layer 171 in contact with the first gate dielectric layer 170 to the surface of the second gate dielectric layer 171 in contact with the gate electrode layer 172. In some embodiments, when viewing the first and second gate dielectric layers 170, 171 as a single layer, the fluorine concentration is the highest at a location that is about 30 percent to about 80 percent of the thickness of the single layer measured from the surface of the first gate dielectric layer 170 in contact with the spacer 137, and the fluorine concentration decreases from the highest point in a first direction towards the spacer 137 and in a second direction towards the gate electrode layer 172.

The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the ILD layer 164. The first and second gate dielectric layers 170, 171 and the gate electrode layer 172 formed over the ILD layer 164 are then removed by using, for example, CMP, until the top surface of the ILD layer 164 is exposed, as shown in FIG. 17.

It is understood that the semiconductor device structure 100 may undergo further processes to form conductive contacts in the ILD layer 164 to be electrically connected to the S/D regions 146 and to form conductive contacts to be electrically connected to the gate electrode layer 172. An interconnect structure may be formed over the semiconductor device structure 100 to provide electrical paths to the devices formed on the substrate 101.

Embodiments of the present disclosure provide a method to form a semiconductor device structure 100. The method includes performing a fluorination process at one or more stages of manufacturing. In some embodiments, the fluorination process is performed after the first gate dielectric layer 170 is formed. As a result, the oxygen vacancies and/or traps in the first and second gate dielectric layers 170, 171 may be passivated by the fluorine, and the fluorine may diffuse into the adjacent spacers 137 and dielectric spacers 144 to lower the k-value thereof. The fluorination process may be performed before or after the dipole process. Additional fluorination processes may be performed to further lower the k-value in the spacers 137 and the dielectric spacers 144. In some embodiments, a first fluorination process is performed after removing the second semiconductor layers 108, which exposes the dielectric spacers 144, and a second fluorination process is performed after the formation of the first gate dielectric layer 170. In some embodiments, a first fluorination process is performed after the formation of the IL 178, and a second fluorination process is performed after the formation of the first gate dielectric layer 170. In some embodiments, a first fluorination process is performed after removing the second semiconductor layers 108, a second fluorination process is performed after the formation of the IL 178, and a third fluorination process is performed after the formation of the first gate dielectric layer 170. The third fluorination process may be performed before or after the dipole process.

In some embodiments, a single fluorination process is performed. For example, the single fluorination process is performed after the formation of the IL 178, and the fluorine may diffuse into the first gate dielectric layer 170 to passivate the oxygen vacancies and/or traps in the first gate dielectric layer 170 after the formation of the first gate dielectric layer 170. In some embodiments, the single fluorination process is performed after the formation of the first gate dielectric layer 170, such as before or after the dipole process. In some embodiments, the single fluorination process is performed after removing the second semiconductor layers 108 and before the formation of the IL 178.

An embodiment is a semiconductor device structure. The structure includes a first gate dielectric layer disposed over a substrate, the first gate dielectric layer includes an inner surface and an outer surface opposite the inner surface, and the first gate dielectric layer includes a fluorine concentration that decreases from the inner surface towards the outer surface. The structure further includes a second gate dielectric layer disposed on the first gate dielectric layer, the first and second gate dielectric layers have a combined thickness, and a thickness of the first gate dielectric layer ranges from about 30 percent to about 80 percent of the combined thickness. The structure further includes a gate electrode layer disposed over the second gate dielectric layer and a spacer disposed adjacent the first gate dielectric layer.

Another embodiment is a method. The method includes forming a fin structure from a substrate, forming a sacrificial gate stack over the fin structure, depositing a spacer on the sacrificial gate stack, removing portions of the fin structure to expose a portion of the substrate, forming a source/drain region from the portion of the substrate, removing the sacrificial gate stack, depositing a first gate dielectric layer, performing a first fluorination process to incorporate fluorine into the first gate dielectric layer, and depositing a second gate dielectric layer on the first gate dielectric layer.

A further embodiment is a method. The method includes forming a fin structure from a substrate, and the fin structure includes a first plurality of semiconductor layers and a second plurality of semiconductor layers. The method further includes forming a sacrificial gate stack over the fin structure, depositing a spacer on the sacrificial gate stack, removing portions of the fin structure to expose a portion of the substrate, recessing the second plurality of semiconductor layers to form cavities, forming dielectric spacers in the cavities, forming a source/drain region from the portion of the substrate, removing the sacrificial gate stack and the second plurality of semiconductor layers, forming an interfacial layer on a portion of each of the first plurality of semiconductor layers, depositing a first gate dielectric layer on the spacer, the dielectric spacers, and the interfacial layer, and depositing a second gate dielectric layer on the first gate dielectric layer. A thickness of the first gate dielectric layer is about 30 percent to about 80 percent of a combined thickness of the first and second gate dielectric layers. The method further includes performing a fluorination process after removing the sacrificial gate stack and the second plurality of semiconductor layers and before depositing the second gate dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first gate dielectric layer disposed over a substrate, wherein the first gate dielectric layer comprises an inner surface and an outer surface opposite the inner surface, and the first gate dielectric layer includes a fluorine concentration that decreases from the inner surface towards the outer surface;
a second gate dielectric layer disposed on the inner surface of the first gate dielectric layer, wherein the first and second gate dielectric layers have a combined thickness, and a thickness of the first gate dielectric layer ranges from about 30 percent to about 80 percent of the combined thickness;
a gate electrode layer disposed over the second gate dielectric layer; and
a spacer disposed adjacent the outer surface of the first gate dielectric layer.

2. The semiconductor device structure of claim 1, wherein the spacer comprises an inner surface facing the first gate dielectric layer and an outer surface opposite the inner surface, and the spacer includes a fluorine concentration that decreases from the inner surface towards the outer surface.

3. The semiconductor device structure of claim 1, further comprising a plurality of semiconductor layers disposed over the substrate, wherein the gate electrode layer surrounds a portion of each of the semiconductor layers.

4. The semiconductor device structure of claim 3, further comprising an interfacial layer in contact with each semiconductor layer of the plurality of semiconductor layers, wherein an interface between the interfacial layer and each semiconductor layer of the plurality of semiconductor layers comprises fluorine.

5. The semiconductor device structure of claim 3, further comprising dielectric spacers disposed between adjacent semiconductor layers of the plurality of semiconductor layers.

6. The semiconductor device structure of claim 5, wherein each of the dielectric spacers comprises an inner surface facing the gate electrode layer and an outer surface opposite the inner surface, and each of the dielectric spacers includes a fluorine concentration that decreases from the inner surface towards the outer surface.

7. A method, comprising:
forming a fin structure from a substrate, wherein the fin structure comprises a first plurality of semiconductor layers;
depositing a spacer over the first plurality of semiconductor layers;
removing portions of the fin structure to expose a portion of the substrate;
forming a source/drain region from the portion of the substrate;
depositing a first gate dielectric layer;
performing a first fluorination process to incorporate fluorine into the first gate dielectric layer; and
depositing a second gate dielectric layer on the first gate dielectric layer.

8. The method of claim 7, wherein the first fluorination process is a fluorine soak process.

9. The method of claim 8, wherein the fluorine soak process is performed at a processing temperature ranging from about 30 degrees Celsius to about 800 degrees Celsius.

10. The method of claim 8, wherein the fluorine soak process is a thermal process.

11. The method of claim 8, wherein the fluorine soak process comprises exposing the first gate dielectric layer to HF, NF₃, CF₄, F₂, C₂F₆, or combinations thereof.

12. The method of claim 7, further comprising performing a dipole process after depositing the first gate dielectric layer.

13. The method of claim 12, wherein the first fluorination process is performed before the dipole process.

14. The method of claim 12, wherein the first fluorination process is performed after the dipole process.

15. The method of claim 7, wherein the fin structure comprises a second plurality of semiconductor layers.

16. A method, comprising:
forming a fin structure from a substrate, wherein the fin structure comprises a first plurality of semiconductor layers and a second plurality of semiconductor layers;
depositing a spacer over the first plurality of semiconductor layers;
removing portions of the fin structure to expose a portion of the substrate;
recessing the second plurality of semiconductor layers to form cavities;
forming dielectric spacers in the cavities;
forming a source/drain region from the portion of the substrate;
removing the second plurality of semiconductor layers;
forming an interfacial layer on a portion of each of the first plurality of semiconductor layers;
depositing a first gate dielectric layer on the spacer, the dielectric spacers, and the interfacial layer;
depositing a second gate dielectric layer on the first gate dielectric layer, wherein a thickness of the first gate dielectric layer is about 30 percent to about 80 percent of a combined thickness of the first and second gate dielectric layers; and
performing a fluorination process after removing the second plurality of semiconductor layers and before depositing the second gate dielectric layer.

17. The method of claim 16, wherein the fluorination process is performed after removing the second plurality of semiconductor layers and before forming the interfacial layer.

18. The method of claim 16, wherein the fluorination process is performed after forming the interfacial layer and before depositing the first gate dielectric layer.

19. The method of claim 16, wherein the fluorination process is performed after depositing the first gate dielectric layer.

20. The method of claim 19, further comprising performing a dipole process after the fluorination process.
